(19) United States
(12) Patent Application Publication
(10) Pub. No.: US 2024/0111256 A1
(43) Pub. Date: Apr. 4, 2024

(54) COMPOSITE DATA FOR DEVICE METROLOGY

(71) Applicant: Onto Innovation Inc., Wilmington, MA (US)

(72) Inventors: Haodong Qiu, SINGAPORE (SG); Zhuo Chen, Boise, ID (US); Wei Ming Chiew, SINGAPORE (SG); Jie Li, San Jose, CA (US); Jingsheng Shi, SINGAPORE (SG); Shashank Srivastava, SINGAPORE (SG)

(73) Assignee: Onto Innovation Inc., Wilmington, MA (US)

(21) Appl. No.: 18/339,982

(22) Filed: Jun. 22, 2023

Related U.S. Application Data
(60) Provisional application No. 63/412,339, filed on Sep. 30, 2022.
(60) Provisional application No. 63/498,474, filed on Apr. 26, 2023.

(51) Int. Cl. G05B 13/02

(52) U.S. Cl. CPC G05B 13/0265; G01N 2201/126

(57) ABSTRACT

A machine learning model that uses composite metrology data determines at least one parameter of a device under test using measured metrology data from the device. The composite metrology data is generated by merging measured metrology data from a reference device with synthetic metrology data calculated from a model of the reference device. The composite metrology data may be generated further based on a synthetic metrology data calculated from a model for a modified reference device. The modified reference device may be generated using variations of at least one parameter of the model to expand the parameter space of the training range.

### CROSS REFERENCE TO RELATED APPLICATIONS

This application claims priority under 35 U.S.C. § 119 to U.S. Provisional Application No. 63/412,339, filed Sep. 30, 2022, entitled “ENHANCED MACHINE LEARNING RECIPE,” and U.S. Provisional Application No. 63/498,474, filed Apr. 26, 2023, entitled “COMPOSITE DATA FOR OPTICAL METROLOGY,” both of which are assigned to the assignee hereof and are incorporated herein by reference in their entireties.

### FIELD OF THE DISCLOSURE

The subject matter described herein is related generally to metrology, and more particularly to training and using a machine learning model for characterizing at least one parameter of a device structure.

### BACKGROUND

Semiconductor and other similar industries often use optical metrology, such as optical metrology or X-ray metrology, to provide non-contact evaluation of samples during processing. With optical metrology, for example, a sample under test is illuminated with light, e.g., at a single wavelength or multiple wavelengths. After the light interacts with the sample, the resulting light is detected and analyzed to determine at least one characteristic of the sample.

Various types of metrology, such as optical critical dimensions (OCD) of device structures, used for process improvement, monitoring, and control, typically employ modeling of the structures under test. The model, for example, may be generated based on the materials and the nominal parameters of the structure, e.g., film thicknesses, line and space widths, etc. Shrinking critical dimensions and smaller error margins combined with increasingly complex structures, such as 3D NAND, are challenging current modeling capabilities.

Machine learning based OCD metrology solutions, and other similar metrology solutions, may be useful when matching to reference metrology data but are limited to scenarios where inline process conditions are similar to those present in the process conditions used for model training. However, robustness is a challenge to machine learning based metrology solutions as there typically is only a limited amount of reference metrology data that is available to train the machine learning recipe. Process variations, especially in the early developing phase, for example, may undermine the utility of the reference metrology data for training the machine learning recipe. This effect is more pronounced when raw spectra data collected from samples after revision of the fabrication process show some level of deviation from the data collected previously and used for model training. A possible solution to this problem is obtaining additional reference metrology data after process revisions and re-training the machine learning model. However, obtaining updated reference metrology data for re-training the machine learning model is inefficient as measurement of reference metrology data can be prohibitively expensive and machine learning model re-training can be time consuming. Moreover, obtaining additional reference metrology data and re-training the machine learning model in response to a process revision does not account for any further process revisions, and must be performed iteratively. Accordingly, improvements are desirable.

### SUMMARY

Metrology of device structures may be performed using machine learning models trained using composite metrology data. The composite metrology data, for example, may be generated by merging measured metrology data from a reference device with synthetic metrology data calculated from a model of the reference device. The composite metrology data may be generated further based on a synthetic metrology data calculated from a model for a modified reference device. The modified reference device is generated using variations of at least one parameter of the model to expand the parameter space of the training range. The composite metrology data may be produced, for example, by modifying the synthetic metrology data calculated from the model for the modified reference device based on a variation, e.g., a misfit or spectral transformation, between the measured metrology data from a reference device and the synthetic metrology data calculated from a model of the reference device. In another implementation, the composite metrology data may be produced by modifying the measured metrology data from the reference device based on a variation, e.g., difference between the synthetic metrology data calculated from a model of the reference device and the synthetic metrology data calculated from the model for the modified reference device. Metrology of device structures may be performed using machine learning models trained using a training data set that includes at least the composite metrology data.

In one implementation, a method for characterizing a device on a sample includes obtaining measured metrology data from the device, and determining, based on the measured metrology data, at least one parameter of the device with a machine learning model that uses composite metrology data. Each composite metrology datum includes a merger of a metrology datum measured for a reference device and a first synthetic metrology datum for a first model of the reference device.

In one implementation, a metrology system configured for supporting characterizing a device on a sample includes a radiation source configured to generate radiation to be incident on the device on the sample, at least one detector configured to detect radiation from the device produced in response to the radiation that is incident on the device, and at least one processor coupled to the at least one detector. The at least one processor is configured to obtain measured metrology data from the device, and to determine, based on the measured metrology data, at least one parameter of the device with a machine learning model that uses composite metrology data. Each composite metrology datum includes a merger of a metrology datum measured for a reference device and a first synthetic metrology datum for a first model of the reference device.

In one implementation, a system configured for supporting characterizing a device on a sample includes means for obtaining measured metrology data from the device, and means for determining, based on the measured metrology data, at least one parameter of the device with a machine learning model that uses composite metrology data. Each composite metrology datum includes a merger of a metrology datum measured for a reference device and a first synthetic metrology datum for a first model of the reference device.

In one implementation, a method for characterizing a device on a sample includes obtaining measured metrology data for a reference device for the device. The method further includes generating a first set of synthetic metrology data for a first model of the reference device and generating a second set of synthetic metrology data for a second model of a modified reference device that is changed with respect to the first model. Composite metrology data is produced for the modified reference device. Each composite metrology datum is produced by merging a measured metrology datum, a first synthetic metrology datum, and a second synthetic metrology datum, and at least the composite metrology data is stored as a training data set.

In one implementation, a computer system configured for supporting characterizing a device on a sample includes at least one processor that is configured to obtain measured metrology data for a reference device for the device. The at least one processor is further configured to generate a first set of synthetic metrology data for a first model of the reference device and generate a second set of synthetic metrology data for a second model of a modified reference device that is changed with respect to the first model. The at least one processor is further configured to produce composite metrology data for the modified reference device. Each composite metrology datum is produced by merging a measured metrology datum, a first synthetic metrology datum, and a second synthetic metrology datum, and to store at least the composite metrology data as a training data set.

In one implementation, a system configured for supporting characterizing a device on a sample includes means for obtaining measured metrology data for a reference device for the device. The system further includes means for generating a first set of synthetic metrology data for a first model of the reference device and generating a second set of synthetic metrology data for a second model of a modified reference device that is changed with respect to the first model. Composite metrology data is produced for the modified reference device. Each composite metrology datum is produced by merging a measured metrology datum, a first synthetic metrology datum, and a second synthetic metrology datum, and at least the composite metrology data is stored as a training data set.

In one implementation, a method for characterizing a device on a sample includes obtaining measured optical metrology data for a reference device for the device and producing composite optical metrology data, wherein each composite optical metrology datum is produced by merging a measured optical metrology datum for the reference device and a first synthetic optical metrology datum for a first model of the reference device. The method further includes training a machine learning model with the training data set comprising at least the composite optical metrology data to characterize the device using measured optical metrology data from the device.

In one implementation, a computer system configured for supporting characterizing a device on a sample includes at least one memory configured to store measured optical metrology data and composite optical metrology data; and at least one processor coupled to the at least one memory. The at least one processor is configured to obtain measured optical metrology data for a reference device for the device, and produce composite optical metrology data, wherein each composite optical metrology datum is produced by merging a measured optical metrology datum for the reference device and a first synthetic optical metrology datum for a first model of the reference device. The at least one processor is further configured to train a machine learning model with the training data set comprising at least the composite optical metrology data to characterize the device using measured optical metrology data from the device.

In one implementation, a computer system for characterizing a device on a sample includes a means for obtaining measured optical metrology data for a reference device for the device and a means for producing composite optical metrology data, wherein each composite optical metrology datum is produced by merging a measured optical metrology datum for the reference device and a first synthetic optical metrology datum for a first model of the reference device. The computer system further includes a means for training a machine learning model with the training data set comprising at least the composite optical metrology data to characterize the device using measured optical metrology data from the device.

### BRIEF DESCRIPTION OF THE DRAWINGS

FIG. 1 illustrates a schematic view of a metrology device that may be used to generate metrology data to produce reference data for training a machine learning model and/or to produce experimental data to characterize parameters of a device structure under test using a trained machine learning model, as described herein.

FIG. 2 illustrates a workflow for offline recipe creation and inline inference based on a training data set including composite metrology data as discussed herein.

FIG. 3 is a graph illustrating a parameter space for metrology using machine learning.

FIG. 4A illustrates a workflow for generation of composite metrology data based on merging measured metrology data and synthetic metrology data to be included in training data.

FIG. 4B illustrates a workflow for generation of composite metrology data by combining synthetic metrology data calculated for a modified reference device with a variation between measured metrology data from a reference device and synthetic metrology data calculated for the reference device.

FIG. 4C illustrates another workflow for generation of composite metrology data by combining synthetic metrology data calculated for a modified reference device with a variation between measured metrology data from a reference device and synthetic metrology data calculated for the reference device.

FIG. 4D illustrates a workflow for generation of composite metrology data by combining measured metrology data from a reference device with a variation between synthetic metrology data calculated for the reference device and synthetic metrology data calculated for a modified reference device.

FIG. 4E illustrates another workflow for generation of composite metrology data by combining measured metrology data from a reference device with a variation between synthetic metrology data calculated for the reference device and synthetic metrology data calculated for a modified reference device.

FIG. 5 illustrates a workflow for generation of composite reference data based on merging parameters values from the reference device and parameter values from models of the reference device and the modified reference device.

FIGS. 6A and 6B illustrate graphs showing a comparison of composite spectra data and measured spectra data for different Mueller Matrix elements.

FIGS. 7A and 7B are graphs illustrating training and testing of a machine learning model trained using only measured spectra.

FIGS. 8A and 8B are graphs illustrating training and testing of a machine learning model trained using composite metrology spectra and measured spectra.

FIGS. 9A and 9B illustrate examples of a device structure with non-key parameters that are strongly correlated with key parameters of the device structure that are to be characterized.

FIG. 10A illustrates graphs showing sample spectra and modeled spectra for a number of Mueller Matrix elements.

FIG. 10B illustrates graphs showing signals from the off-diagonal Mueller Matrix components that correspond to asymmetrical parameters.

FIG. 11 shows an illustrative flowchart depicting an example operation for supporting characterizing a device on a sample, according to implementations described herein.

FIG. 12 shows an illustrative flowchart depicting an example operation for supporting characterizing a device on a sample, according to implementations described herein.

FIG. 13 shows an illustrative flowchart depicting an example operation for supporting characterizing a device on a sample, according to implementations described herein.

### DETAILED DESCRIPTION

During fabrication of semiconductor devices and similar devices it is often necessary to monitor the fabrication process by non-destructively measuring the devices. One type of metrology that may be used for non-destructive measurement of samples during processing is optical metrology, which may use a single wavelength or multiple wavelengths, and may include, e.g., ellipsometry, reflectometry, Fourier Transform infrared spectroscopy (FTIR), etc. Other types of metrology may also be used, including X-ray metrology, opto-acoustic metrology, electron beam (E-beam) metrology, etc.

Optical metrology, such as thin film metrology and Optical Critical Dimension (OCD) metrology, and other types of metrology, sometimes use physical modeling of the device structure, e.g., sometimes referred to herein as OCD modeling or using an OCD model, or simply as modeling or using a model. Simulated metrology data, e.g., simulated optical data, may be calculated for the physical model using rigorous coupled-wave analysis (RCWA), Finite-Difference Time-Domain (FDTD) or Finite Element Method (FEM), or other similar techniques. Variable parameters in the physical model, such as layer thicknesses, line widths, space widths, sidewall angles, material properties, etc., may be adjusted and the simulated data is calculated for each variation. The data measured from the device structure may be compared to the simulated data for each parameter variation, e.g., in a nonlinear regression process, until a good fit is achieved, at which time the values of the fitted parameters are determined to be an accurate representation of the parameters of the device structure. Techniques using physical modeling, however, have a high computation cost due to the calculations required to simulate metrology data. As device structures become more complex, such techniques become less useful due to the slow time to solution and limits in the model accuracy.

Machine learning is another technique that may be used for metrology of various parameters of a device structure for process improvement, monitoring, and control. Unlike modeling, machine learning does not use a physical model. Instead, training data is obtained from reference samples and used to train a machine learning model. The training data, for example, may include spectral signals and the values of structure parameters of interests from reference samples. The machine learning models are automatically “trained” based on the training data to find relevant spectral features and to learn the intrinsic relationships and connections between input and output features in order to make decisions and predictions for new data.

One of the challenges for metrology using machine learning is the robustness of the machine learning training. For example, generally there is only a limited amount of reference data available to train the machine learning model, which inherently limits the predictions that can be generated by the machine learning model. For example, training data may be obtained based on measured data from at least one reference device. However, measured data is limited to the number of reference devices available and, accordingly, there is a practical limit to variations in parameters from the reference devices that may be present in training data acquired in this manner. Moreover, fabrication process revisions may occur over time, e.g., while developing the device structure, which may reduce the relevance of training data obtained from earlier acquired measurements. While additional training data may be obtained by producing and measuring additional reference devices based on the process revisions and the machine learning model re-trained using the newly acquired training data, this process is inefficient as measurement of reference metrology data is expensive and re-training time consuming. Additionally, the process of obtaining new training data and re-training the machine learning model may need to be performed iteratively for each process revision.

Another challenge is that some key parameters to be measured, such as overlay, may have low sensitivity. Accordingly, problems with the training data may occur due to the signal size of the key parameter and/or system noise in the training data set. Moreover, non-key parameters, e.g., with stronger signals, may be highly correlated to the key parameter. For example, overlay breaks structural symmetry in a device, resulting in spectral responses in the off-diagonal components of the Mueller Matrix; however, the magnitude of these off-diagonal components is low. Moreover, a non-key parameter such as tilt, may be highly correlated to overlay when there is structural asymmetry. Accordingly, it may be challenging to measure overlay using conventional spectral fitting with only an OCD model. While machine learning may be used for measurement, the robustness of machine learning recipes is closely related to the design of experiment (DOE), and the quality and quantity of the references for the training data set. A common failure mode, for example, is related to process variations. When process variations are not included in the DOE and the affected parameters have strong correlations with overlay, the machine learning recipe will behave poorly by attributing the spectral responses of such process variation to overlay, leading to inaccurate predictions and requiring recipe rework.

The training data may be augmented using synthetic (simulated) data calculated from physical models. For example, physical modeling techniques, such as an OCD modeling may be used to generate synthetic metrology data for variations in at least one parameter in the physical model, which may be used to increase the training sample parameter space for better process variation coverage. However, synthetic metrology data has limited utility as training data. For example, synthetic training data cannot be easily adopted directly for use in applications with key parameters that have low sensitivity, such as overlay measurement. For example, in applications with key parameter signals that are relatively small, the physical model needs to be extremely accurate to generate useful synthetic metrology data. Moreover, measured data contains system noise which may vary by system, wafer, environment, and the time of the measurements. It is difficult to determine if synthetic metrology data generated by a physical model simulating the key parameter is accurate or overfitting system noise. Additionally, synthetic metrology data does not include system noise. Accordingly, when synthetic metrology data and measured data are separately collected together as training data, a machine learning model may not extract the correct measurement information from both and may treat one as an outlier.

As discussed herein, to overcome the limitations of using only measured data, or a collection of measured data and separate synthetic metrology data as training data, composite metrology data may be generated and used as training data. The composite metrology data is a mixture of measured metrology data and synthetic metrology data. Thus, instead of merely collecting measured metrology data and synthetic metrology data separately into a training data set, measured metrology data and synthetic metrology data are merged together to form a composite metrology data. The composite metrology data may be included in the training data set. In some implementations, the composite metrology data and measured metrology data may be included in the training data set. For the sake of reference, the metrology data used to produce the composite metrology data is sometimes described herein as optical data or in particular spectral data, but it should be understood that other types of metrology data may be used, such as X-ray data, opto-acoustic data, and E-beam data.

The composite metrology data is generated utilizing measured metrology data from a reference device, a first set of synthetic metrology data from a first model of the reference device (e.g., an accurate model after fitting to the measured metrology data), and a second set of synthetic metrology data from a second model of a modified reference device (e.g., at least one parameter of the first model are varied to produce the second model of the modified reference device). In some implementations, for example, the second set of synthetic metrology data may be modified based on variations between the measured metrology data and the first set of synthetic metrology data, while in other implementations, the measured metrology data may be modified based on variations between the first set of synthetic metrology data and the second set of metrology data.

In some implementations, the at least one parameter of the first model varied to produce the second model of the modified reference device may include key parameters, which will increase the parameter space for the training data set. Composite reference data associated with the composite metrology data may be generated, e.g., by merging values of the reference parameters, the fitted parameters and the changed parameters, and used as labels in the training data set.

In some implementations, the at least one parameter of the first model varied to produce the second model of the modified reference device may be non-key parameters. The non-key parameters, for example, may be parameters that strongly correlate with the key parameter. Thus, the composite metrology data may be produced based on the measured metrology data and synthetic metrology data generated from variations in highly correlated non-key parameters. The composite metrology data may be associated with the reference values for the key parameters as labels in the training data set.

Accordingly, with the use of composite metrology data, the machine learning recipe is able to tolerate a variety of process variations without preparing actual wafers with extensive process coverage for machine learning recipe creation.

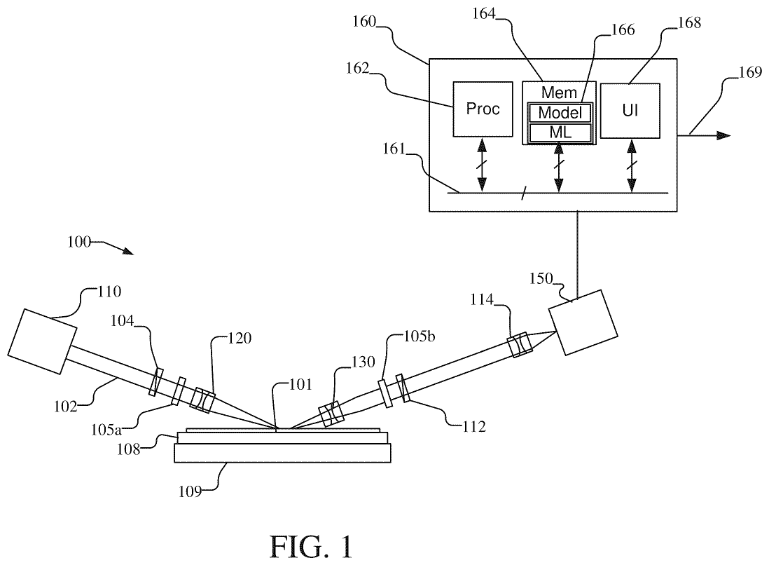

FIG. 1, by way of example, illustrates a schematic view of a metrology device 100 that may be used to generate metrology data to produce reference data for training a machine learning model and/or to produce experimental data to characterize parameters of a device structure under test using a trained machine learning model, as described herein. The metrology device 100 is illustrated as an optical metrology device, but other types of metrology devices may be used, such as X-ray, opto-acoustic, or E-beam metrology devices. The optical metrology device 100 may be configured to perform, e.g., spectroscopic reflectometry, spectroscopic ellipsometry (including Mueller matrix ellipsometry), spectroscopic scatterometry, overlay scatterometry, interferometry, or FTIR measurements, of a sample 101. The sample 101, for example, may include at least one device structure to be measured. It should be understood that optical metrology device 100 is illustrated as one example of a metrology device, and that if desired other metrology devices may be used, including normal incidence devices, non-polarizing devices, etc.

Metrology device 100 includes a source 110 that produces radiation that is incident on the sample. The metrology device 100 in FIG. 1 is illustrated as an optical metrology device 100 and thus, the source is a light source 110 that produces light 102, but other types of metrology devices may use sources that produce other types of radiation, such as X-ray or E-beams. The light 102 produced by light source 110 may include a range of wavelengths, i.e., continuous range or a plurality of discrete wavelengths, for example, UV-visible light with wavelengths, e.g., between 200 nm and 1000 nm; or may be a single wavelength. The optical metrology device 100 includes focusing optics 120 and 130 that focus and receive the light and direct the light to be obliquely incident on a top surface of the sample 101. The optics 120, 130 may be refractive, reflective, or a combination thereof and may be an objective lens.

The reflected light may be focused by lens 114 and received by a detector 150. The detector 150 may be a conventional charge coupled device (CCD), photodiode array, CMOS, or similar type of detector. The detector 150 may be, e.g., a spectrometer if broadband light is used, and detector 150 may generate a spectral signal as a function of wavelength. A spectrometer may be used to disperse the full spectrum of the received light into spectral components across an array of detector pixels. One or more polarizing elements may be in the beam path of the optical metrology device 100. For example, optical metrology device 100 may include one or both (or none) of one or more polarizing elements 104 in the beam path before the sample 101, and a polarizing element (analyzer) 112 in the beam path after the sample 101, and may include one or more additional elements 105a and 105b, such as a compensator or photoelastic modulator, which may be before, after, or both before and after the sample 101. With the use of a spectroscopic ellipsometer using dual rotating compensators, between polarizing elements 104 and 112 and the sample, a full Mueller matrix may be measured.

Optical metrology device 100 further includes one or more computing systems 160 that is configured to perform measurements of at least one parameter of the sample 101 using the methods described herein. The one or more computing systems 160 is coupled to the detector 150 to receive the metrology data acquired by the detector 150 during measurement of the structure of the sample 101. The acquisition of data may be to generate reference data from one or more reference devices for training a machine learning model and/or for generating experimental data from a device under test to characterize at least one parameter of the device. The one or more computing systems 160, for example, may be a workstation, a personal computer, central processing unit or other adequate computer system, or multiple systems. The one or more computing systems 160 may be configured to perform optical metrology based on spectral processing or based on processing any other desired type of optical metrology data or other metrology data, e.g., in accordance with the methods described herein.

It should be understood that the one or more computing systems 160 may be a single computer system or multiple separate or linked computer systems, which may be interchangeably referred to herein as computing system 160, at least one computing system 160, one or more computing systems 160. The computing system 160 may be included in or is connected to or otherwise associated with optical metrology device 100. Different subsystems of the optical metrology device 100 may each include a computing system that is configured for carrying out steps associated with the associated subsystem. The computing system 160, for example, may control the positioning of the sample 101, e.g., by controlling movement of a stage 109 that is coupled to the chuck. The stage 109, for example, may be capable of horizontal motion in either Cartesian (i.e., X and Y) coordinates, or Polar (i.e., R and θ) coordinates or some combination of the two. The stage may also be capable of vertical motion along the Z coordinate. The computing system 160 may further control the operation of the chuck 108 to hold or release the sample 101. The computing system 160 may further control or monitor the rotation of one or more polarizing elements 104, 112, or elements 105a and 105b, which may be a compensator or photoelastic modulator, etc.

The computing system 160 may be communicatively coupled to the detector 150 in any manner known in the art. For example, the one or more computing systems 160 may be coupled to a separate computing system that is associated with the detector 150. The computing system 160 may be configured to receive and/or acquire metrology data or information from one or more subsystems of the optical metrology device 100, e.g., the detector 150, as well as controllers polarizing elements 104, 112, and elements 105a, 105b, etc., by a transmission medium that may include wireline and/or wireless portions. The transmission medium, thus, may serve as a data link between the computing system 160 and other subsystems of the optical metrology device 100.

The computing system 160 includes at least one processor 162 with memory 164, as well as a user interface (UI) 168, which are communicatively coupled via a bus 161. The memory 164 or other non-transitory computer-usable storage medium, includes computer-readable program code 166 embodied thereof and may be used by the computing system 160 for causing the one or more computing systems 160 to control the optical metrology device 100 and to perform the functions including any one or more of the generation of composite metrology data, training a machine learning model using composite metrology data, or characterizing parameters of a device structure using a machine learning model trained with composite metrology data, as described herein. For example, as illustrated, memory 164 may include instructions for causing the processor 162 to perform both physical modeling and machine learning (ML), as discussed herein. The data structures and software code for automatically implementing one or more acts described in this detailed description can be implemented by one of ordinary skill in the art in light of the present disclosure and stored, e.g., on a computer-usable storage medium, e.g., memory 164, which may be any device or medium that can store code and/or data for use by a computer system, such as the computing system 160. The computer-usable storage medium may be, but is not limited to, include read-only memory, a random access memory, magnetic and optical storage devices such as disk drives, magnetic tape, etc. Additionally, the functions described herein may be embodied in whole or in part within the circuitry of an application specific integrated circuit (ASIC) or a programmable logic device (PLD), and the functions may be embodied in a computer understandable descriptor language which may be used to create an ASIC or PLD that operates as herein described.

The computing system 160, for example, may be configured to obtain optical metrology data from a plurality of measurement sites on one or more samples, e.g., calibration or training samples. Each measurement site includes a device structure, and the optical metrology data may include spectral signals or other types of optical metrology data. The computing system 160 may be configured to generate metrology solutions for optical measurement of the device structure as discussed herein, including using modeling and machine learning to generate composite metrology data for training a machine learning model. In some implementations, a different computing system and/or different optical metrology device may be used to acquire the reference data from training samples, to generate composite metrology data, to train the machine learning model using the composite metrology data, or to characterize at least one parameter of a device structure under test using a machine learning model trained with composite metrology data. The reference data, the training set of data including the composite metrology data, or the trained machine learning model may be provided to the computing system 160, e.g., via the computer-readable program code 166 on non-transitory computer-usable storage medium, such as memory 164.

The reference data, the training set of data including the composite metrology data, or the trained machine learning model may be stored in memory 164. Further results of the analysis of the data, e.g., to characterize the parameters of a device structure under test may be reported, e.g., stored in memory 164 associated with the sample 101 and/or indicated to a user via UI 168, an alarm or other output device. Moreover, the results from the analysis may be reported and fed forward or back to the process equipment to adjust the appropriate fabrication steps to compensate for any detected variances in the fabrication process. The computing system 160, for example, may include a communication port 169 that may be any type of communication connection, such as to the internet or any other computer network. The communication port 169 may be used to receive instructions that are used to program the computing system 160 to perform any one or more of the functions described herein and/or to export signals, e.g., with measurement results and/or instructions, to another system, such as external process tools, in a feed forward or feedback process in order to adjust a process parameter associated with a fabrication process step of the samples based on the measurement results.

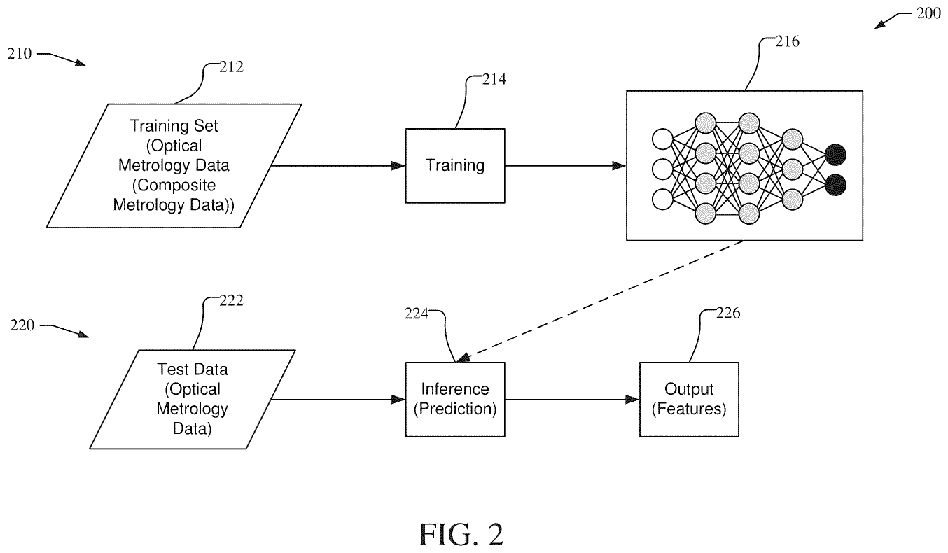

FIG. 2, by way of example, illustrates a workflow 200 for offline recipe creation and inline inference based on a training data set as discussed herein. As illustrated, during a learning phase 210 a training set of metrology data 212 is provided. The training set of metrology data 212, for example, may include composite metrology data that is generated based on a combination of theoretically calculated metrology data (synthetic metrology data) and experimentally measured metrology data (measured metrology data) obtained from one or more reference structures using optical metrology device 100, as discussed herein. For example, each composite metrology datum is a combination of a measured metrology datum and a synthetic metrology datum. The synthetic metrology data may cover a wider variation of the process conditions than the measured metrology data. The training set of metrology data 212 may further include the experimentally measured data, e.g., metrology data measured from one or more reference structures. At least a portion of the training set of metrology data 212 may be labeled based on key parameter reference values.

As illustrated, training 214 is performed based on the training set of metrology data 212. For example, the training may include feature extraction, regression, classification, and other techniques to generate a machine learning model 216. For example, the training 214 may use any desired machine learning algorithm that may use composite metrology data as at least part of the training set of metrology data 212. For example, the machine learning algorithm may be a supervised or unsupervised learning algorithm.

The machine learning model 216 trained using a training data set that includes the composite metrology data, as discussed herein, may be used for measurement of at least one parameter of a device under test. With the use of composite metrology data to train the machine learning model 216, the machine learning model 216 is able to tolerate a variety of process variations better than if only measured metrology data, only pure synthetic metrology data, or a combination of measured metrology data and pure synthetic metrology data in the training set of metrology data 212. In some implementations, the at least one parameter that may be measured with the machine learning model 216 may include key parameters that have low sensitivity, such as overlay, because the composite metrology data reduces or eliminates problems due to the signal size of the key parameter and system noise in the training data set.

During an inference phase 220, test data 222 (e.g., optical metrology data) is obtained from a device structure under test, e.g., using optical metrology device 100 shown in FIG. 1. The test data 222, for example, may be the same type of metrology data used in the training set of metrology data 212. Using the test data 222 as input data, the trained machine learning model 216 may be used to infer or predict (224) and output 226 a value of the desired features, e.g., the parameter of interest of the device structure under test. Because the machine learning model 216 is trained on the composite metrology data, which is exposed to a wider variation of the process conditions, the model predictions may have better metrology performance in the event of a process revision if the composite metrology data better represents the experimental metrology data after the process revision.

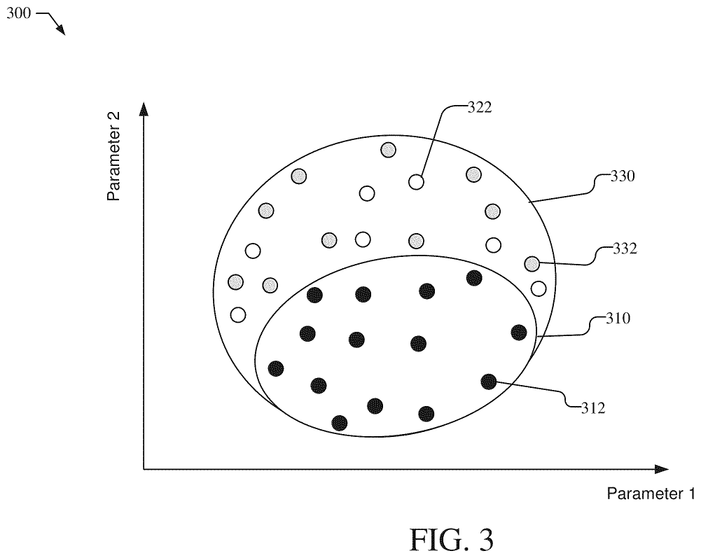

FIG. 3 is a graph 300 illustrating a parameter space for metrology using machine learning. The parameter space illustrated in graph 300 includes two parameters, parameter 1 along the X axis, and parameter 2 along the Y axis. As illustrated using black circles in graph 300, reference targets with parameter variations are measured to produce a number of training samples 312, which define a training range 310 in the parameter space. The measurements of a device under test that has parameters within the training range 310 will be relatively accurate, but the accuracy degrades when parameters are outside the training range 310. For example, as illustrated using white circles, test samples 322 generated by measuring devices with parameters outside the training range 310 will result in degraded accuracy. Devices with parameters outside the training range 310, for example, may be produced due to fabrication process variations that occur after the initial training samples 312 are obtained.

To extend the training range, additional training data may be obtained. As illustrated by gray circles, composite training samples 332 may be obtained, thereby producing an extended training range 330. As illustrated, the extended training range 330 includes the test samples 322 and thus is sufficient to produce an acceptable accuracy for the test samples 322. Each composite training sample 332 is generated based on a combination of measured metrology data and synthetic metrology data. The synthetic metrology data, for example, may be generated by including some perturbation to reference data, e.g., the training samples 312. The synthetic metrology data is then combined with the reference data, e.g., the training samples 312 to produce the composite training sample 332 with parameters that are outside the training range 310. As a result, the parameter space defined by the composite training samples is expanded from the initial training range 310.

The machine learning model may be trained using the composite data, i.e., a training data set that includes both the training range 310 and the extended training range 330, and is thus exposed to a wider variation of the process conditions than if trained only on the training range 310. Accordingly, the predictions from the training machine learning model may have better metrology performance in the event of a process revision, e.g., if the composite metrology data is a better representation of the measured data after the process revision.

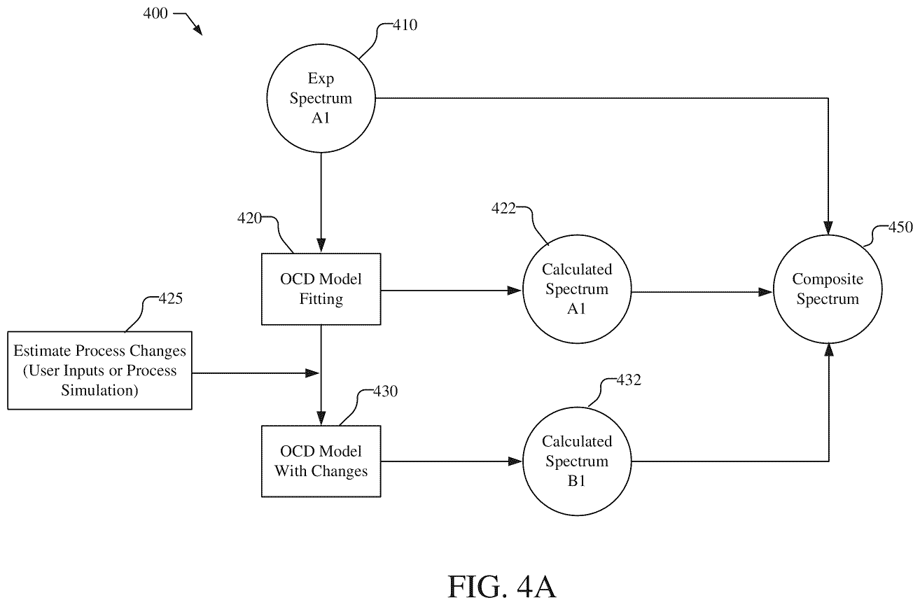

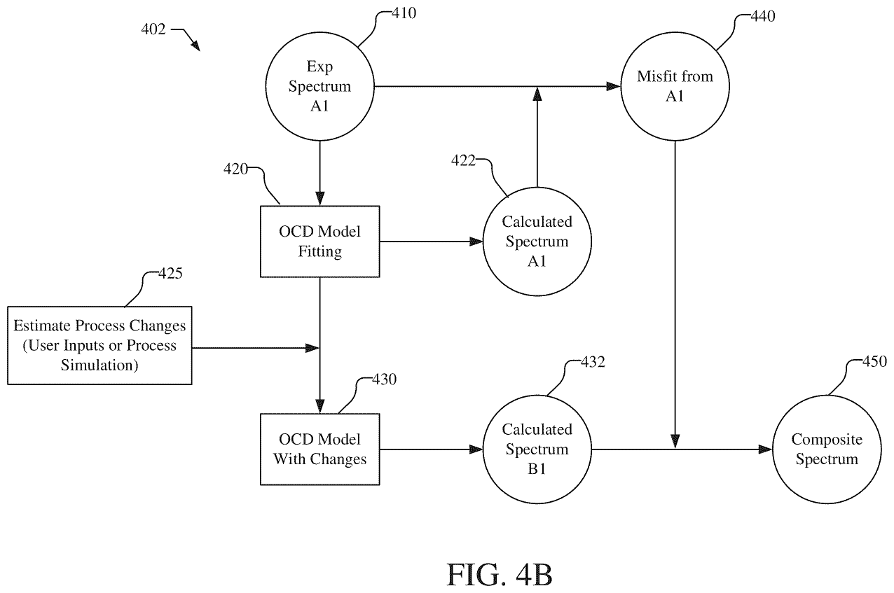

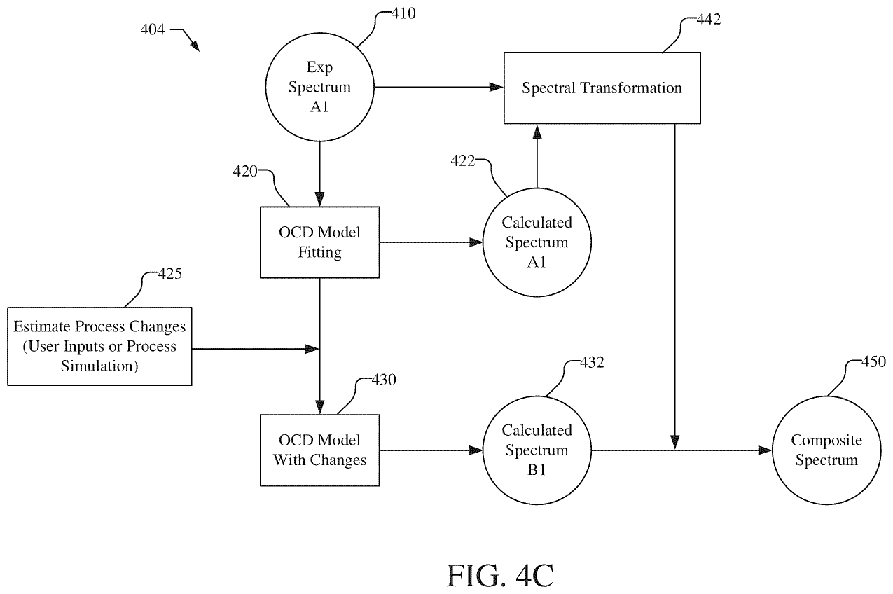

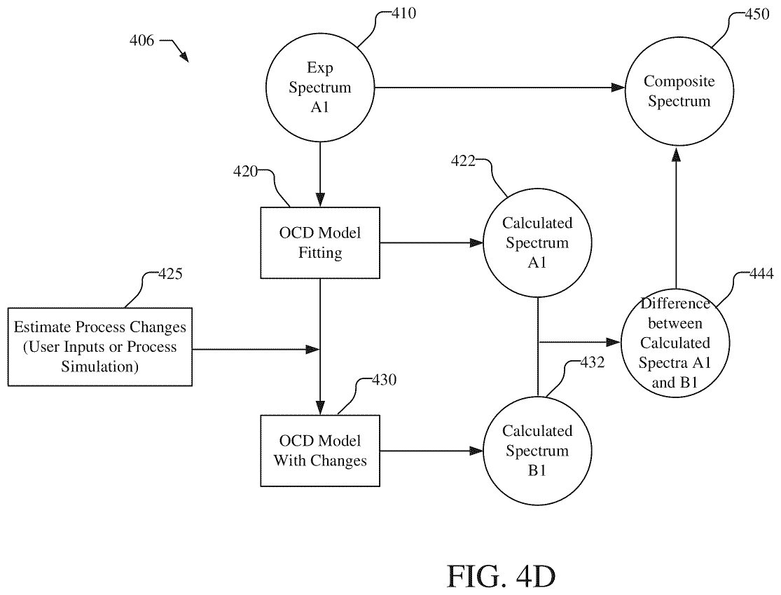

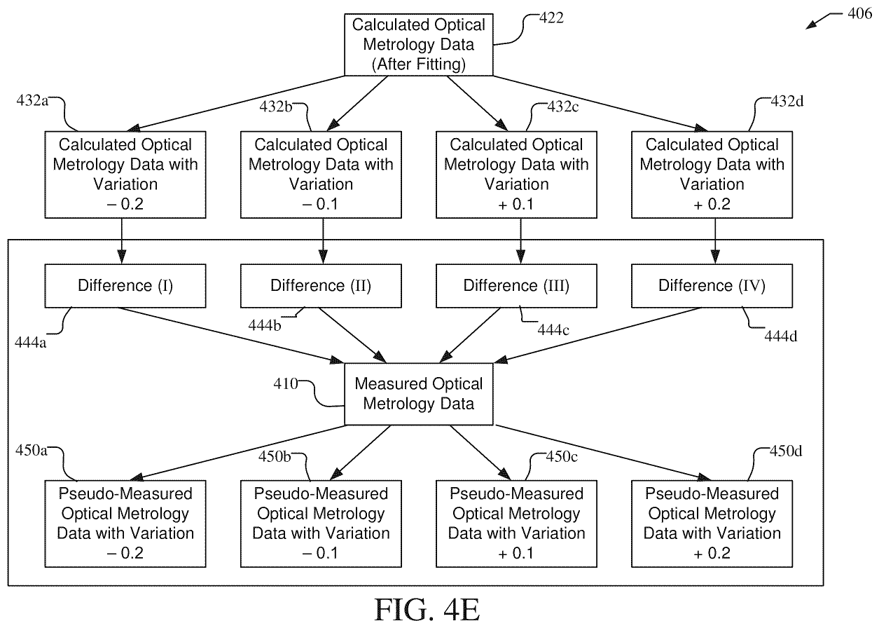

FIG. 4A illustrates a workflow 400 for generation of composite metrology data based on merging measured metrology data and synthetic metrology data to be included in training data. The composite metrology data is generated based on a combination of measured metrology data and synthetic metrology data. For the sake of reference, the metrology data discussed herein, e.g., the composite metrology data, measured metrology data, and synthetic metrology data, is sometimes described as optical metrology data and in particular, spectral data, but it should be understood that other types of metrology data may be used.

As illustrated at block 410, measured metrology data is obtained from a reference device having a first set of parameters, which may represent process conditions A1 (experimental spectrum A1). The reference device, for example, may be generated using the same fabrication process as the device to be tested (process conditions A1), but may have at least one parameter intentionally altered from its nominal value. The measured metrology data from block 410, for example, may be obtained from a reference device by optical metrology device 100 shown in FIG. 1.

At block 420, the measured metrology data (experimental spectrum A1) is fit to a physical model. For example, a first model, e.g., an OCD model, may be produced based on values of the at least one parameter for the reference device, which may be known, e.g., based on CD-SEM or other similar types of measurements of the reference structure or other similar reference structures. Calculated metrology data is generated for the physical model using a modeling technique, such as RCWA, FDTD, FEM, etc., which is fit to the measured metrology data. For example, various parameters of the physical model may be adjusted, and the calculated metrology data produced for each variation is compared to the measured metrology data, e.g., in a nonlinear regression process, until a good fit is achieved. Once a good fit is achieved, the values of the fitted parameters for the physical model are considered to be an accurate representation of the parameters of the reference device.

The calculated metrology data that corresponds to the best fit with the measured metrology data from block 420 is produced as a first set of synthetic metrology data for the reference device with the first set of parameters representing process conditions A1 (e.g., calculated spectrum A1) at block 422.

Additionally, as illustrated at block 430, a second model is produced with changes with respect to the first model to simulate a modified reference device. For example, at least one parameter of the first model from block 420 may be changed to produce the second model. The changes to at least one parameter for the second model, for example, may be greater than any of the variations in the parameters found in reference devices representing process conditions A1. In some implementations, the at least one parameter changed for the second model may be geometrical parameters and optical constants that are changed to mimic changes due to anticipated revised process conditions B 1, which may be obtained from user input or through process simulation as illustrated at block 425.

For example, OCD model parameters that are susceptible to variation due to changes in process conditions may be altered by some perturbation, which may be defined for a parameter P as follows:

P_{Perturbed}=P_{OCD_Fit}+random_perturbation(P_{OCD_Fit}) Eq. 1
where P_{Perturbed} is the parameter P after perturbation, P_{OCD_Fit} is the result for parameter P after fitting the OCD model with the experimental spectra A1 (at block 420). The random perturbation as a function of P_{OCD_Fit} may be defined as follows:

random_perturbation(P_{OCD_Fit}=B+factor*std_dev(P_{OCD_Fit})*rand_num Eq. 2
where B corresponds to a bias term to incorporate design of experiment (DOE) conditions, factor is a multiplication factor that controls the variance of random perturbations and may be, e.g., between 0.1 and 10, std_dev is the standard deviation and rand_num is a random number that may range between, e.g., −0.5 and 0.5, but any desired range may be used, such as −1 and 1, 0.1 and 10, etc.

The one or more parameters that are varied may be key parameters, non-key parameters, or both key parameters and non-key parameters. In some implementations, key parameters of the models may be held static and only non-key parameters in the physical model may be varied. For example, if the key parameter is overlay, the same overlay value may be used in the first model and the second model, but other non-key parameters may be varied. The non-key parameter may be strongly correlated with the key parameter. For example, in some device structures, a bit line tilt parameter in the structure may be strongly correlated with overlay, e.g., variations in tilt produce similar changes in the optical metrology data as variations in overlay. Other examples of parameters that may be correlated to overlay may be layer thickness or critical dimension.

At block 432, using a modeling technique, such as RCWA, FDTD, FEM, etc., calculated metrology data may be generated for the second model as a second set of synthetic metrology data for the modified reference device with a second set of parameters, which may represent process conditions B1 (e.g., calculated spectrum B1).

As illustrated, based on a combination of the measured metrology data (experimental spectrum A1) from block 410, the first set of synthetic metrology data (calculated spectrum A1) from block 422, and the second set of synthetic metrology data (calculated spectrum B1) from block 432, composite metrology data may be produced (composite spectrum). By way of example, in some implementations, a variation between the measured metrology data (experimental spectrum A1) and the first set of synthetic metrology data (calculated spectrum A1) may be determined, which may then be combined with the second set of synthetic metrology data (calculated spectrum B1) to produce the composite metrology data (composite spectrum). The variation, for example, may be the misfit between the measured metrology data and the synthetic metrology data or may be a spectral transformation between the measured metrology data and the synthetic metrology data. In other implementations, a variation between the first set of synthetic metrology data (calculated spectrum A1) and the second set of synthetic metrology data (calculated spectrum B1) may be determined, which may then be combined with the measured metrology data (experimental spectrum A1) to produce the composite metrology data (composite spectrum). The variation between the first set of synthetic metrology data and the second set of synthetic metrology data, for example, may be the difference between the synthetic metrology data.

The resulting composite metrology data at block 450, accordingly, is similar to the measured metrology data from block 410 but includes changes in the parameter space extending the training range, e.g., as illustrated by extended training range 330 in FIG. 3.

The process of generating composite metrology data, illustrated in FIG. 4A, may be performed for each separate measured metrology data, e.g., measured metrology data obtained from different reference devices with different parameter values, and may be repeated for different variations of the parameters to generate a plurality of composite metrology data. The composite metrology data, and in some implementations, the measured metrology data, may be combined to form the training set of metrology data 212 (shown in FIG. 2).

The composite metrology data, thus, is based on measured metrology data, but also includes simulated variations in the metrology data introduced by variations in at least one parameter. The machine learning model 216 (shown in FIG. 2) thus is trained using the composite metrology data to extend the parameter space thereby increasing utility. Further, the synthetic information combined with measured metrology data, may be used to help the machine learning model break the metrology data correlation of non-key parameters, but does not create any new key parameter data. Accordingly, the resulting machine learning model 216 trained using the composite metrology data will be robust and able to tolerate a variety of process variations, without requiring a large amount of measured reference data.

FIG. 4B illustrates a workflow 402 for an implementation of generation of composite metrology data based on merging of measured metrology data and synthetic metrology data to produce training data. The workflow 402 is similar to workflow 400 shown in FIG. 4A, like designated elements being the same.

Similar to workflow 400 shown in FIG. 4A, at block 410, measured metrology data is obtained from a reference device having a first set of parameters, which may represent process conditions A1 (experimental spectrum A1). The measured metrology data (experimental spectrum A1) is fit to a physical model at block 420 and the calculated metrology data that corresponds to the best fit with the measured metrology data is produced as a first set of synthetic metrology data for the reference device with the first set of parameters representing process conditions A1 (e.g., calculated spectrum A1) at block 422.

At block 430, a second model is produced simulating a modified reference device, e.g., with one or more parameters changed with respect to the parameters used in the first model from block 420, and calculated metrology data is generated for the second model as a second set of synthetic metrology data for the modified reference device with a second set of parameters, which may represent process conditions B1 (e.g., calculated spectrum B1) at block 432.

As illustrated in FIG. 4B at block 440, a variation between the measured metrology data (experimental spectrum A1) at block 410 and the first set of synthetic metrology data (calculated spectrum A1) from block 422 may be determined as the misfit between the measured metrology data (experimental spectrum A1) and the first set of synthetic metrology data (calculated spectrum A1). For example, the misfit spectra may be determined as:

Misfit Spectra=experimental spectra A1−OCD Best Fit Spectra(Process Condition A1) Eq. 3
where the OCD Best Fit Spectra is the calculated spectrum A1.

The misfit from block 430, which is based on the measured metrology data from block 410 and the first set of synthetic metrology data from block 422, may be added to the second set of synthetic metrology data from block 432 to produce the composite metrology data representing process conditions B1 at block 450.

FIG. 4C illustrates a workflow 404 for an implementation of generation of composite metrology data based on merging combination of measured metrology data and synthetic metrology data to produce training data. The workflow 404 is similar to workflow 400 shown in FIG. 4A, like designated elements being the same.

Similar to workflow 400 shown in FIG. 4A, at block 410, measured metrology data is obtained from a reference device having a first set of parameters, which may represent process conditions A1 (experimental spectrum A1). The measured metrology data (experimental spectrum A1) is fit to a physical model at block 420 and the calculated metrology data that corresponds to the best fit with the measured metrology data is produced as a first set of synthetic metrology data for the reference device with the first set of parameters representing process conditions A1 (e.g., calculated spectrum A1) at block 422.

At block 430, a second model is produced simulating a modified reference device, e.g., with one or more parameters changed with respect to the parameters used in the first model from block 420, and calculated metrology data is generated for the second model as a second set of synthetic metrology data for the modified reference device with a second set of parameters, which may represent process conditions B1 (e.g., calculated spectrum B1) at block 432.

As illustrated in FIG. 4C at block 442, a variation between the measured metrology data (experimental spectrum A1) at block 410 and the first set of synthetic metrology data (calculated spectrum A1) from block 422 may be determined as a spectral transformation between the measured metrology data (experimental spectrum A1) and the first set of synthetic metrology data (calculated spectrum A1). For example, a mathematical model is generated to transform the first set of synthetic metrology data (calculated spectrum A1) to measured metrology data (experimental spectrum A1) for the process conditions A1.

The transformation determined in block 442, which is based on the measured metrology data from block 410 and the first set of synthetic metrology data from block 422, may then be applied to the second set of synthetic metrology data from block 432 to produce the composite metrology data representing process conditions B1 at block 450.

FIG. 4D illustrates a workflow 406 for an implementation of generation of composite metrology data based on merging measured metrology data and synthetic metrology data to produce training data. The workflow 406 is similar to workflow 400 shown in FIG. 4A, like designated elements being the same.

Similar to workflow 400 shown in FIG. 4A, at block 410, measured metrology data is obtained from a reference device having a first set of parameters, which may represent process conditions A1 (experimental spectrum A1). The measured metrology data (experimental spectrum A1) is fit to a physical model at block 420 and the calculated metrology data that corresponds to the best fit with the measured metrology data is produced as a first set of synthetic metrology data for the reference device with the first set of parameters representing process conditions A1 (e.g., calculated spectrum A1) at block 422.

At block 430, a second model is produced simulating a modified reference device, e.g., with one or more parameters changed with respect to the parameters used in the first model from block 420, and calculated metrology data is generated for the second model as a second set of synthetic metrology data for the modified reference device with a second set of parameters, which may represent process conditions B1 (e.g., calculated spectrum B1) at block 432.

As illustrated in FIG. 4D at block 444, a variation between the first set of synthetic metrology data (calculated spectrum A1) from block 422 and the second set of synthetic metrology data (calculated spectrum B1) from block 432 may be determined as a spectral difference. For example, the spectral difference may be determined as:

Spectral Difference=OCD Best Fit Spectra(Process Condition A1)−OCD Spectra(Process Condition B1) Eq. 4
where the OCD Best Fit Spectra is the calculated spectrum A1 and the OCD Spectra is the calculated spectrum B1.

The spectral difference from block 444, which is based on the first set of synthetic metrology data from block 422 and the second set of synthetic metrology data from block 432, may be added to the measured metrology data from block 410 to produce the composite metrology data representing process conditions B1 at block 450.

FIG. 4E illustrates a more detailed view of workflow 406, shown in FIG. 4D, for an implementation of generation of composite metrology data based on merging measured metrology data and synthetic metrology data to produce training data, in which a spectral difference between the first set of synthetic metrology data and the second set of synthetic metrology data is used.

As illustrated in FIG. 4E, a first set of synthetic metrology data is obtained (calculated metrology data) at block 422. The calculated metrology data from block 422, for example, may be obtained based on fitting measured metrology data from block 410, to a first physical model (as illustrated at block 420 in FIG. 4D). The physical model, e.g., an OCD model, may be used to generated based on values of the key parameter for the reference structure (and any other parameters), which may be known, e.g., based on CD-SEM or other similar types of measurements of the reference structure. Calculated metrology data is generated for the physical model and fit to the measured data in a nonlinear regression process, until a good fit is achieved, at which time the values of the fitted parameters for the physical model are determined to be an accurate representation of the parameters of the reference structure.

As illustrated, a second set of synthetic metrology data is generated (calculated metrology data) at blocks 432a, 432b, 432c, and 432d (sometimes collectively referred to as blocks 432) for variations to one or more non-key parameters in a second physical model (as illustrated in block 430 in FIG. 4D), i.e., using the same reference value for the key parameter used in the first model. For example, if the key parameter is overlay, the same overlay value is used in the first physical model to generate the calculated metrology data in block 422 and second physical models to generate the calculated optical metrology data in blocks 432. The calculated metrology data in blocks 432 may be generated for the second physical models using the same modeling technique, e.g., RCWA, FDTD, FEM, etc., used to generate the calculated metrology data in block 422. In some implementations, the non-key parameter that is varied to generate the calculated metrology data in blocks 432 may be strongly correlated with the key parameter. As in the example discussed above, in some device structures a bit line tilt parameter in the structure may be strongly correlated with overlay, e.g., variations in tilt produce similar changes in the metrology data as variations in overlay. Other examples of parameters that may be correlated to overlay may be layer thickness or critical dimension. FIG. 4E illustrates the calculated metrology data from blocks 432a, 432b, 432c, and 432d determined for four variations of a non-key parameter having values −0.2, −0.1, +0.1, and +0.2, respectively, as an example. It should be understood that additional or fewer variations may be used and that the values of the variations may be different and may depend on the type of non-key parameter being varied and the number of variations.

The difference between the first set of synthetic metrology data from the first model from block 422 and the second set of synthetic metrology data from blocks 432 is calculated to generate differences (I, II, III, and IV) at blocks 444a, 444b, 444c, and 444d (sometimes collectively referred to as blocks 444). The differences determined at blocks 444 represent the changes in the metrology data due to variations in the non-key parameters (with the value of the key parameter fixed).

As illustrated, the measured metrology data from block 410 may be modified based on the differences from blocks 444 to generate the composite metrology data for each variation in the non-key parameters at blocks 450a, 450b, 450c, and 450d (sometimes collectively referred to as blocks 450). For example, each of the differences from blocks 444 may be added to the measured metrology data from block 410, which is the measured metrology data that is used for fitting to produce the calculated metrology data from block 422 and has the same reference value for the key parameter as used in the first set of synthetic metrology data from block 422 and the second set of synthetic metrology data from block 432. The resulting composite metrology data in blocks 450, accordingly, is similar to the measured metrology data from block 410 as it has the same reference value for the key parameter and system noise, but includes changes in the metrology data due to variations in the non-key parameters.

The process of generating composite metrology data, illustrated in FIGS. 4D and 4E, may be performed for each separate measured metrology data, e.g., having a different key parameter value, to generate a plurality of composite metrology data for each measured metrology data. The composite metrology data, and in some implementations, the associated measured metrology data, may be combined to form the training set of metrology data 212 (shown in FIG. 2).

The composite metrology data, thus, is based on measured metrology data, but includes simulated differences in the metrology data that is introduced by variations in non-key parameters, which in some implementations may be highly correlated to the key parameters. The machine learning model 216 (shown in FIG. 2) thus is trained using composite metrology that has the same key parameter reference values as the measured metrology data. The composite metrology data, which incorporates synthetic information with the measuring information, may be used to help the machine learning model break the metrology data correlation of non-key parameters, but does not create any new key parameter data. Accordingly, a physical model does not need to fit for the key parameter, which reduces or eliminates problems associated with signal sensitivity associated with the key parameter and the presence of system noise in the reference data but not the synthetic metrology data. Accordingly, the resulting machine learning model 216 trained using the composite data will be robust and able to tolerate a variety of process variations, without requiring a large amount of measured reference data.

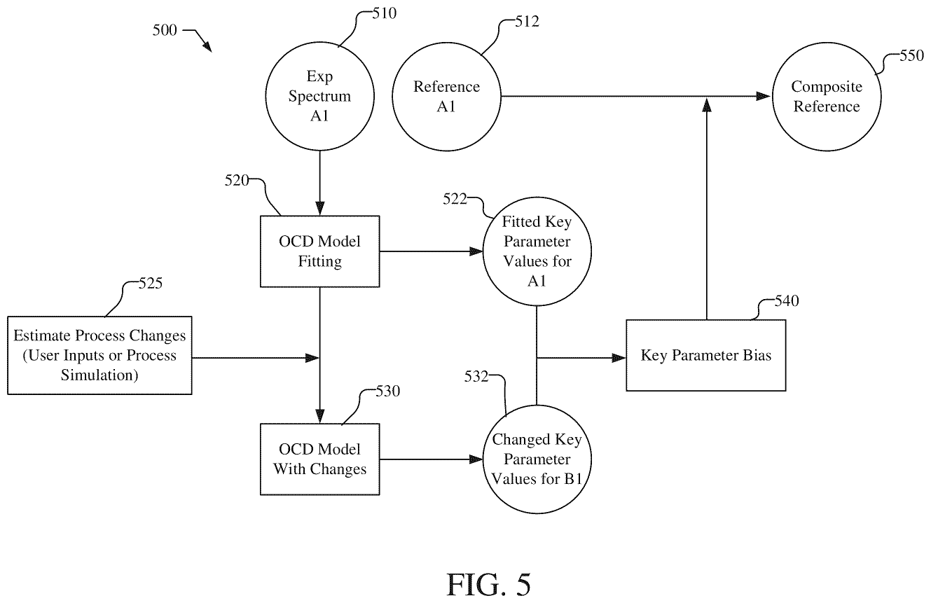

FIG. 5 illustrates a workflow 500 for an implementation of generation of composite reference data based on merging parameters values from the reference device and parameter values from models of the reference device and the modified reference device. The workflow 500 produces composite reference data that may be included with the training data, e.g., training set of metrology data 212 in FIG. 2, along with composite metrology data, e.g., if key parameters are varied in the second model as discussed in reference to workflows 400, 402, and 404 in FIGS. 4A, 4B, and 4C, respectively. Composite reference data produced by workflow 500 may not be necessarily included in the training data if the key parameters are not varied in the second model, as discussed in reference to workflow 406 in FIGS. 4D and 4E.

At block 510, similar to block 410 in FIG. 4A, measured metrology data is obtained from a reference device having a first set of reference parameters, which may represent process conditions A1 (experimental spectrum A1). The reference parameters from the reference device are illustrated at block 512 (reference A1). The values for the reference parameters may be known, e.g., based on CD-SEM or other similar types of measurements of the reference structure or other similar reference structures.

At block 520, the measured metrology data (experimental spectrum A1) is fit to a physical model and may be the same process performed at block 420 in FIG. 4B, e.g., by fitting the measured metrology data to calculated metrology data and adjusting parameters of the physical model using a nonlinear regression process, until a good fit is achieved. Once a good fit is achieved, the values of the fitted parameters for the physical model are considered to be an accurate representation of the parameters of the reference device. The resulting parameter values from the fitting process in block 520 are produced as a first set of key parameter values for the first model of the reference device at block 522 (fitted key parameter values for A1).

As illustrated at block 530, a second model is produced with changes to key parameters with respect to the first model to simulate a modified reference device by changing values of one or more key parameters of the first model from block 520, e.g., based on the application of changes that represent estimated process variations for the device, which may be obtained from user input or through process simulation as illustrated at block 525, which may represent process conditions B1. It is understood that non-key parameters may be changed as well with respect to the first model that represents possible process variations for the device. The generation of the second model produced at block 530 may be the same process performed at block 430 in FIG. 4B. At block 532, the parameter values for the second model are produced as a second set of key parameter values for the second model (changed key parameter values for B1).

At block 540, a key parameter bias is determined based on the first set of key parameter values from block 522 and the second set of key parameter values from block 532. For example, a parameter bias is the difference between the expected parameter value and the actual parameter value. Thus, in block 540, the key parameter bias may be determined as a difference between the first set of key parameter values from block 522 and the second set of key parameter values from block 532. The key parameter bias is then combined with the reference parameter from block 512 to generate a composite reference at block 550. The composite reference data may be used as labels for process B1 in the training set of data.

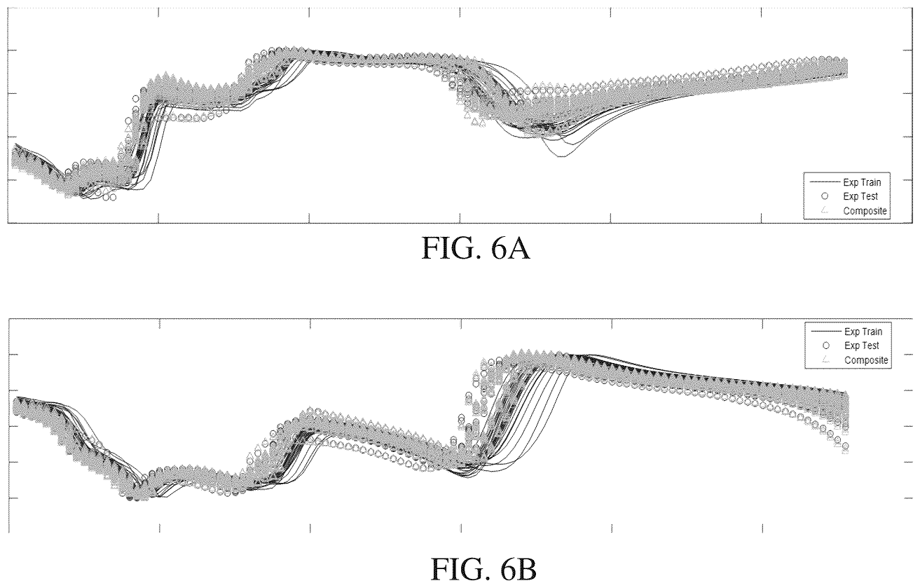

FIGS. 6A and 6B, by way of example, are graphs illustrating a comparison of composite spectra data and measured spectra data for a number of Mueller Matrix elements (M33 and M34, respectively). The “Exp Train” curves are experimental spectra generated from references under process condition A, and “Exp Test” curves are experimental spectra generated from references under process condition B. The “Composite” curves are composite spectra data generated after applying changes representing the change between process condition A and B, as discussed herein.

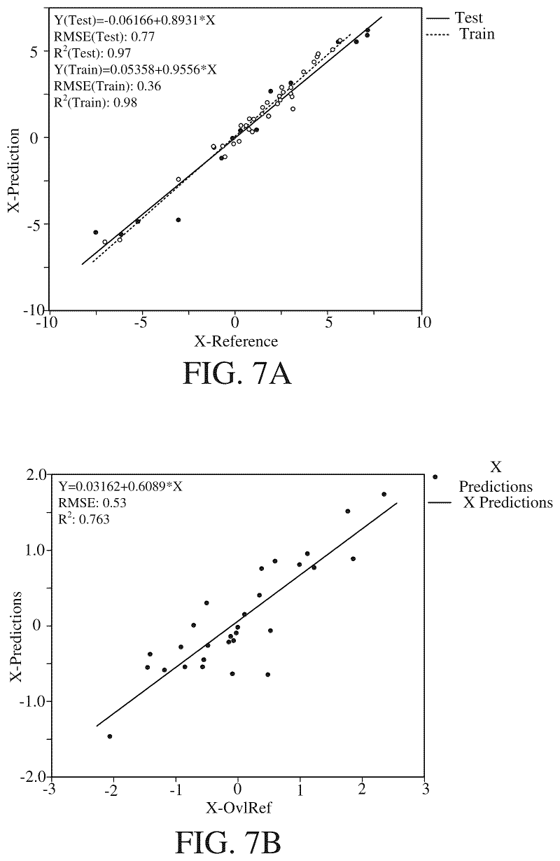

FIG. 7A, by way of example, is a graph illustrating the performance during training of a machine learning model using only measured reference optical metrology data (spectra) and illustrating the training and testing (verification) of the training model. FIG. 7B illustrates a blind test of the machine learning model from FIG. 7A. As illustrated, the blind test results in an accuracy (R²) of 0.763 with a slope of 0.609 and a root means square error (RMSE) of 0.53.

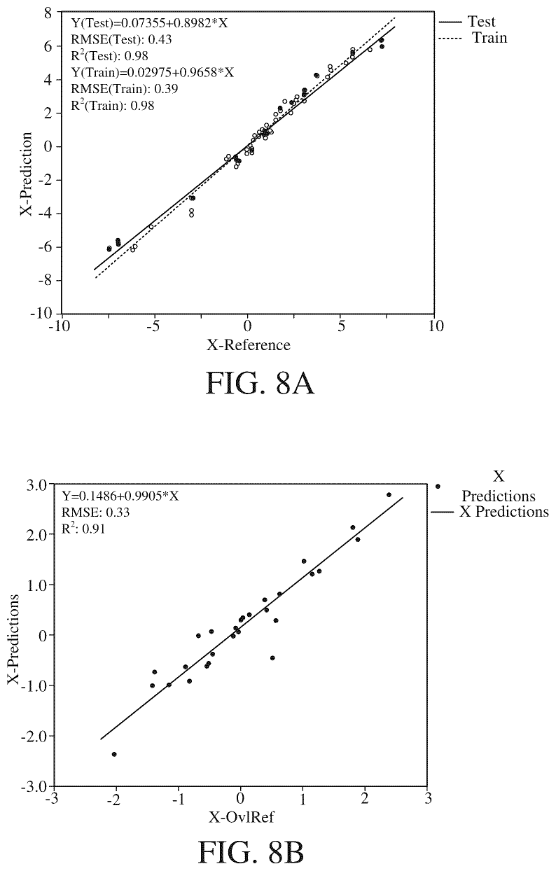

In contrast, FIG. 8A is a graph illustrating the performance during training of a machine learning model using composite optical metrology data (spectra) and measured reference optical metrology data (spectra) and illustrating the training and testing (verification) of the training model. FIG. 8B illustrates a blind test of the machine learning model from FIG. 8A. As illustrated, the blind test results in higher accuracy that shown FIG. 7B with an accuracy (R²) of 0.91 with a slope of 0.991 and a root means square error (RMSE) of 0.33.

As discussed above, composite metrology data may be useful for measurement of key parameters that have low sensitivity, such as overlay, because the composite metrology data reduces or eliminates problems due to the signal size of the key parameter and system noise in the training data set. Overlay, for example, breaks structural symmetry, resulting in spectral responses in the off-diagonal components of the Mueller Matrix; however, the magnitude of those off-diagonal components is low. Moreover, several parameters may be highly correlated to overlay when there is structural asymmetry.

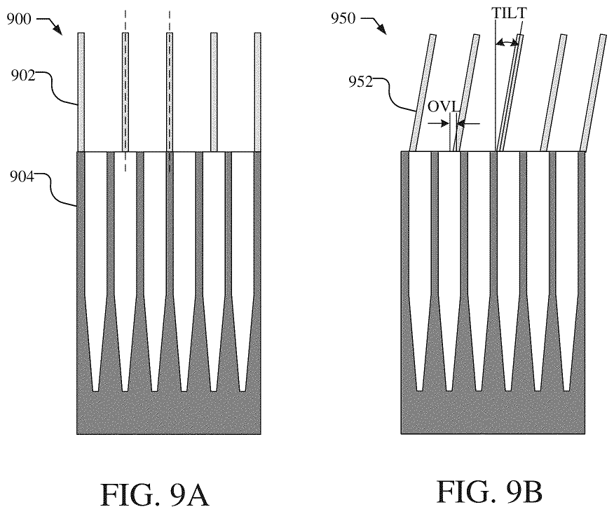

FIG. 9A, by way of example, illustrates an example of a device structure 900 having key parameters that have low sensitivity that may be measured using metrology techniques, such as discussed herein. The device structure 900 is illustrated as a simplified DRAM gate including a plurality of bitlines 902 aligned with underlying structures 904. FIG. 9A, for example, illustrates with dotted lines the process expectation for overlay and tilt for the bitlines 902. FIG. 9B, by way of example, illustrates an example of a device structure 950, similar to device structure 900, but with a non-zero overlay (OVL) error, and non-zero tilt of the bitlines 952. The overlay error OVL, for example, may be a key parameter for characterizing the device structure via optical metrology. The tilt of the bitlines 952, or other parameters, such as the critical dimension or thickness, may be non-key parameters, but may be strongly correlated with the overlay error OVL. In other words, variations in a non-key parameter, such as tilt, may strongly influence the same optical metrology data used to determine the overlay error OVL, making it difficult to measure overlay.

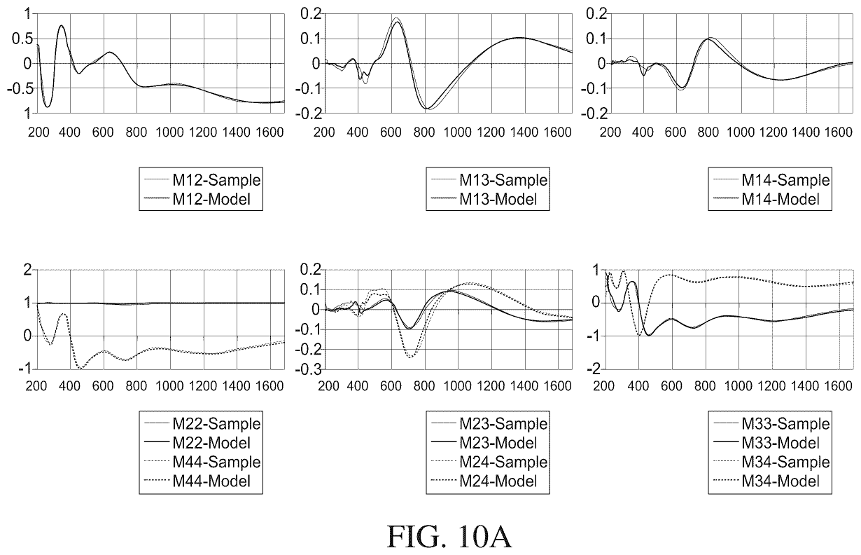

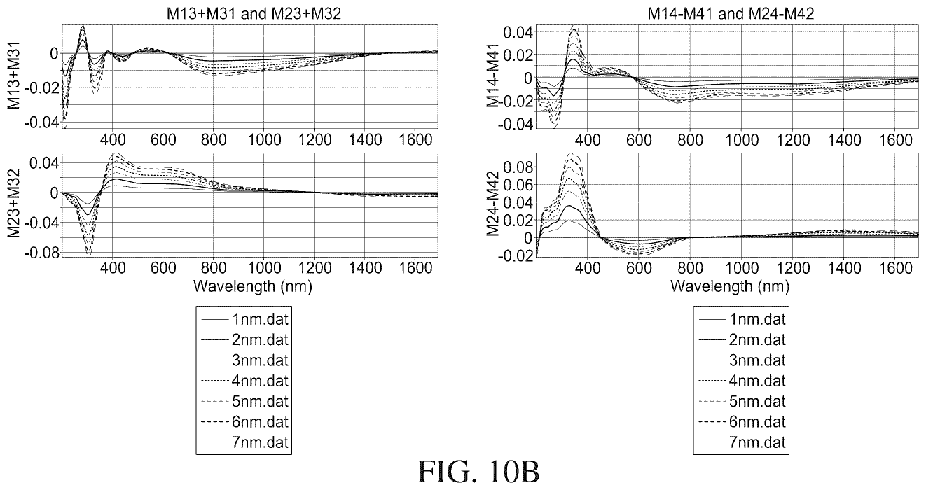

FIG. 10A, by way of example, are graphs illustrating sample spectra and modeled spectra for a number of Mueller Matrix elements, i.e., M12, M13, M14, M22, M23, M24, M33, M34, and M44, for which a good fit between the sample and model spectra has been achieved using conventional physical modeling techniques to measure thickness and OCD parameters. FIG. 10B, in contrast, illustrates asymmetrical signals from off-diagonal Mueller Matrix components that correspond to overlay and tilt. As can be seen in FIG. 10B, the sensitivity of the signals for overlay and tilt is significantly lower than the fit that can be achieved through physical modeling techniques, as illustrated in FIG. 10A.

With the use of composite metrology data, as discussed herein, the machine learning model 216 shown in FIG. 2 may be trained using a training data set that includes the composite metrology data for measurement of key parameters with low sensitivity, such as overlay, because the composite metrology data reduces or eliminates problems due to the signal size of the key parameter and system noise in the training data set. Accordingly, with the use of composite metrology data, the machine learning model 216 is able to tolerate a variety of process variations better than if pure synthetic metrology data is used with the measured data in the training set of metrology data 212.

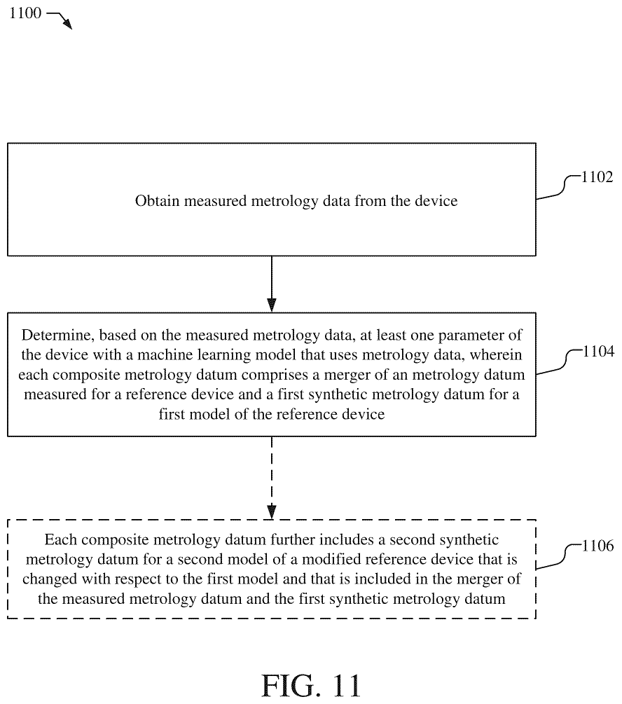

FIG. 11 shows an illustrative flowchart depicting an example operation 1100 for supporting characterizing a device on a sample, according to some implementations. In some implementations, the example operation 1100 may be performed by a metrology device, such as metrology device 100 with one or more processors, e.g., such as processor 162 in computing system 160 in FIG. 1.

The one or more processors may obtain measured metrology data from the device (1102). For example, a means for obtaining the measured metrology data from the device may be the metrology device 100 and interface with the processor 162 in computing system 160 shown in FIG. 1. The measured metrology data, for example, may be the test data 222 shown in FIG. 2.

The one or more processors may determine, based on the measured metrology data, at least one parameter of the device with a machine learning model that uses composite metrology data. Each composite metrology datum includes a merger of a metrology datum measured for a reference device and a first synthetic metrology datum for a first model of the reference device (1104), e.g., as discussed to the learning phase 210 and inference phase 220 shown in FIG. 2 and generating of the training data illustrated in workflows 400, 402, 404, and 406 in FIGS. 4A-4E. A means for determining, based on the measured metrology data, at least one parameter of the device with a machine learning model that uses composite metrology data, wherein each composite metrology datum comprises a merger of a metrology datum measured for a reference device and a first synthetic metrology datum for a first model of the reference device may be, e.g., the metrology device 100, including the computing system 160 with the processor 162 configured to perform as a machine learning model by the computer-readable program code 166, shown in FIG. 1. In some optional implementations, as illustrated with dashed lines, each composite metrology datum may comprise the merger of the metrology datum and the first synthetic metrology datum and further a second synthetic metrology datum for a second model of a modified reference device that is changed with respect to the first model (1106), e.g., as discussed to the learning phase 210 and inference phase 220 shown in FIG. 2 and generating of the training data illustrated in workflows 400, 402, 404, and 406 in FIGS. 4A-4E.

The one or more processors may provide, e.g., report, the at least one parameter of the device to characterize the device on the sample. For example, a means for providing the at least one parameter of the device to characterize the device on the sample may be the metrology device 100 and interface with the processor 162 and memory 164 in computing system 160 and the UI 168 shown in FIG. 1.

In some implementations, the second model of the modified reference device has at least one parameter that is varied with respect to the first model, e.g., as discussed in blocks 430 of FIGS. 4A-4E.

In some implementations, the machine learning model may further use composite reference parameters for the modified reference device based on a merger of reference parameters of the reference device, a first set of key parameter values generated for the first model, and a second set of key parameters values generated for the second model, e.g., as discussed at blocks 540, 512, and 550 of FIG. 5.

In some implementations, the first model may be produced by fitting metrology data measured from the reference device to synthetic optical metrology data for the first model, e.g., as discussed at block 420 in FIGS. 4A-4E.

In some implementations, the second model of the modified reference device may be produced by changing at least one parameter of the first model, e.g., as discussed at block 430 in FIGS. 4A-4E.

In some implementations, second synthetic metrology data for the second model of the modified reference device may be generated based on a variation between metrology data measured from the reference device and first synthetic metrology data for the first model, e.g., as discussed in reference to FIG. 4A and illustrated at blocks 440, 442, and 450 in FIGS. 4B and 4C. The variation between the metrology data measured from the reference device and the first set of synthetic metrology data for the first model, for example, may be a misfit between the metrology data and the first synthetic metrology data, as discussed at block 440 in FIG. 4B, or a spectral transformation between the metrology data and the first synthetic metrology data as illustrated at block 442 in FIG. 4C.

In some implementations, the composite metrology data may be generated by modifying metrology data measured from the reference device with a determined difference between first synthetic metrology data for the first model and second synthetic metrology data for the second model of the modified reference device, e.g., as discussed in reference to FIG. 4A and illustrated at block 444 and 450 in FIGS. 4D and 4E.

In some implementations, the composite metrology data may include a plurality of sets of composite metrology data for a corresponding plurality of modified reference devices.

In some implementations, the measured metrology data includes measured spectra and the composite metrology data includes composite spectra.

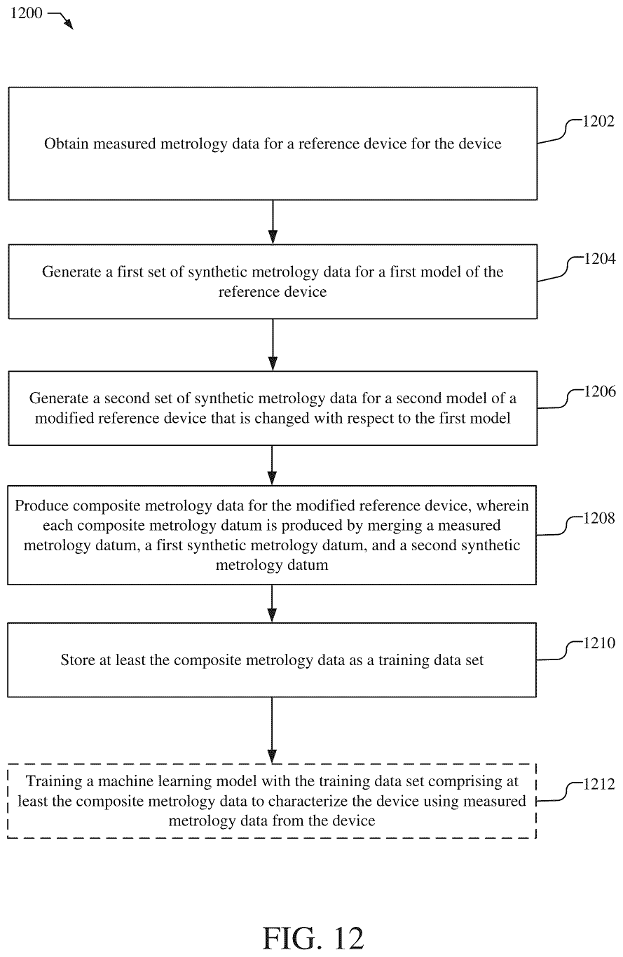

FIG. 12 shows an illustrative flowchart depicting an example operation 1200 for supporting characterizing a device on a sample, according to some implementations. In some implementations, the example operation 1200 may be performed by a metrology device, such as metrology device 100 with at least one processor, e.g., such as processor 162 in computing system 160 in FIG. 1.

The at least one processor may obtain measured metrology data for a reference device for the device (1202). For example, a means for obtaining measured metrology data for the reference device may be the metrology device 100 and interface with the processor 162 in computing system 160 shown in FIG. 1. The measured metrology data, for example, may be reference data with known values of key parameters, such as overlay. The measured overlay metrology data, for example, may be the measured metrology data from block 410 shown in FIGS. 4A-4E, and block 510 shown in FIG. 5.

The at least one processor may generate a first set of synthetic metrology data for a first model of the reference device (1204). For example, the first set of synthetic metrology data may be the calculated metrology data shown in blocks 422 of FIGS. 4A-4E. A means for generating a first set of synthetic metrology data for a first model of the reference device may be the metrology device 100, including the computing system 160 with processor 162 configured by the computer-readable program code 166 shown in FIG. 1.

The at least one processor may generate a second set of synthetic metrology data for a second model of a modified reference device that is changed with respect to the first model (1206). For example, the second set of synthetic metrology data may be the calculated metrology data shown in blocks 432 of FIGS. 4A-4E. A means for generating a second set of synthetic metrology data for a second model of a modified reference device that is changed with respect to the first model may be the metrology device 100, including the computing system 160 with processor 162 configured by the computer-readable program code 166 shown in FIG. 1.

The at least one processor may produce composite metrology data for the modified reference device, each composite metrology datum being produced by merging a measured metrology datum, a first synthetic metrology datum, and a second synthetic metrology datum (1208). For example, the composite metrology data may be the produced composite metrology data shown in block 450 in FIGS. 4A-4E. A means for producing composite metrology data for the modified reference device, each composite metrology datum being produced by merging a measured metrology datum, a first synthetic metrology datum, and a second synthetic metrology datum may be the metrology device 100, including the computing system 160 with processor 162 configured by the computer-readable program code 166 shown in FIG. 1.

The at least one processor may store at least the composite metrology data as a training data set (1210), e.g., in memory 164 shown in FIG. 1. The training data set, for example, may be the training set of metrology data 212 shown in FIG. 2 and discussed in reference to FIGS. 4A-4E. A means for may store at least the composite metrology data as a training data set may be the metrology device 100, including the computing system 160 with processor 162 configured by the computer-readable program code 166, and memory 164 in computing system 160 shown in FIG. 1.

In some optional implementations, the at least one processor may further train a machine learning model with the training data set including at least the composite metrology data to characterize the device using measured metrology data from the device (1212), e.g., as illustrated by training 214 a machine learning model 216 with the training set of metrology data 212 shown in FIG. 2.

In some implementations, at least one processor may generate the first model by fitting the measured metrology data to the first set of synthetic metrology data for the first model, e.g., as discussed at block 420 in FIGS. 4A-4E.

In some implementations, at least one processor may generate the second model of the modified reference device by changing at least one parameter of the first model, e.g., as discussed at block 430 in FIGS. 4A-4E.

In some implementations, at least one processor may produce the composite metrology data for the modified reference device by determining a variation between the measured metrology data and the first set of synthetic metrology data, e.g., as discussed in reference to FIG. 4A and illustrated at blocks 440 and 442 in FIGS. 4B and 4C. The at least one processor may further modify the second set of synthetic metrology data with the variation between the measured metrology data and the first set of synthetic metrology data as discussed in reference to FIG. 4A and illustrated at blocks 440, 442, and 450 in FIGS. 4B and 4C. The variation between the measured metrology data and the first set of synthetic metrology data, for example, may be a misfit between the measured metrology data and the first set of synthetic metrology data, as discussed at block 440 in FIG. 4B, or a spectral transformation between the measured metrology data and the first set of synthetic metrology data as illustrated at block 442 in FIG. 4C.

In some implementations, at least one processor may produce the composite metrology data for the modified reference device by determining a difference between the first set of synthetic metrology data and the second set of synthetic metrology data, e.g., as discussed in reference to FIG. 4A and illustrated at block 444 in FIGS. 4D and 4E. The at least one processor may further modify the measured metrology data with the difference between the first set of synthetic metrology data and the second set of synthetic metrology data as discussed in reference to FIG. 4A and illustrated at block 444 and 450 in FIGS. 4D and 4E.

In some implementations, at least one processor may further produce a plurality of sets of composite metrology data for a corresponding plurality of modified reference devices and store the plurality of sets of the composite metrology data as the training data set.

The measured metrology data, for example, may be measured spectra and the first set of synthetic metrology data and the second set of synthetic metrology data may be synthetic spectra.

In some implementations, at least one processor may further generate a first set of key parameter values for the first model of the reference device, e.g., as discussed at block 522 of FIG. 5. The at least one processor may further generate a second set of key parameter values for the second model, e.g., as discussed at block 532 of FIG. 5. The at least one processor may produce composite reference parameters for the modified reference device by merging the reference parameters, the first set of key parameter values and the second set of key parameters values, e.g., as discussed at blocks 512, 540, and 550. The at least one processor may store the composite reference parameters with the composite metrology data as the training data set, e.g., in memory 164 shown in FIG. 1. For example, the composite reference parameters for the modified reference device may be produced by determining a key parameter bias between the first set of key parameter values and the second set of key parameters values, e.g., as discussed at block 540 of FIG. 5, and modifying the reference parameters with the key parameter bias, e.g., as discussed at block 550 of FIG. 5.

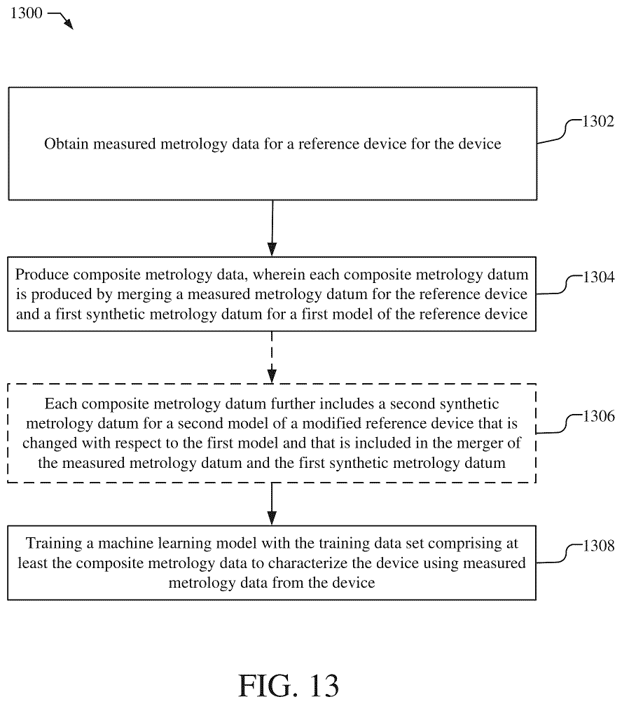

FIG. 13 shows an illustrative flowchart depicting an example operation 1300 for supporting characterizing a device on a sample, according to some implementations. In some implementations, the example operation 1300 may be performed by a metrology device, such as metrology device 100 with at least one processor, e.g., such as processor 162 in computing system 160 in FIG. 1.

The at least one processor may obtain measured metrology data for a reference device for the device (1302). For example, a means for obtaining measured metrology data for the reference device may be the metrology device 100 and interface with the processor 162 in computing system 160 shown in FIG. 1. The measured metrology data, for example, may be reference data with known values of key parameters, such as overlay. The measured overlay metrology data, for example, may be the measured metrology data from block 410 shown in FIGS. 4A-4E, and block 510 shown in FIG. 5.

The at least one processor may produce composite metrology data, each composite metrology datum being produced by merging a measured metrology datum for the reference device with a first synthetic metrology datum for a first model of the reference device (1304). For example, the composite metrology data may be the produced composite metrology data shown in block 450 in FIGS. 4A-4E. In some implementations, the first set of synthetic metrology data may be the calculated metrology data shown in blocks 422 of FIGS. 4A-4E. A means for producing composite metrology data, each composite metrology datum being produced by merging a measured metrology datum for the reference device with a first synthetic metrology datum for a first model of the reference device may be the metrology device 100, including the computing system 160 with processor 162 configured by the computer-readable program code 166 shown in FIG. 1. In some optional implementations, as illustrated with dashed lines, each composite metrology datum may comprise the merger of the metrology datum and the first synthetic metrology datum and further a second synthetic metrology datum for a second model of a modified reference device that is changed with respect to the first model (1306), and the composite metrology data may be for the modified reference device, e.g., as discussed to the learning phase 210 and inference phase 220 shown in FIG. 2 and generating of the training data illustrated in workflows 400, 402, 404, and 406 in FIGS. 4A-4E. In some implementations, the second set of synthetic metrology data may be the calculated metrology data shown in blocks 432 of FIGS. 4A-4E.

The at least one processor trains a machine learning model with a training data set that includes at least the composite metrology data to characterize the device using measured metrology data from the device (1308), e.g., as illustrated by training 214 a machine learning model 216 with the training set of metrology data 212 shown in FIG. 2. A means for training a machine learning model with a training data set that includes at least the composite metrology data to characterize the device using measured metrology data from the device may be, e.g., the metrology device 100, including the computing system 160 with processor 162 configured by the computer-readable program code 166 shown in FIG. 1.

In some implementations, at least one processor may generate the first model by fitting the measured metrology data to the first set of synthetic metrology data for the first model, e.g., as discussed at block 420 in FIGS. 4A-4E.

In some implementations, at least one processor may generate the second model of the modified reference device by changing at least one parameter of the first model, e.g., as discussed at block 430 in FIGS. 4A-4E.

In some implementations, at least one processor may produce the composite metrology data for the modified reference device by determining a variation between the measured metrology data and the first set of synthetic metrology data, e.g., as discussed in reference to FIG. 4A and illustrated at blocks 440 and 442 in FIGS. 4B and 4C. The at least one processor may further modify the second set of synthetic metrology data with the variation between the measured metrology data and the first set of synthetic metrology data as discussed in reference to FIG. 4A and illustrated at blocks 440, 442, and 450 in FIGS. 4B and 4C. The variation between the measured metrology data and the first set of synthetic metrology data, for example, may be a misfit between the measured metrology data and the first set of synthetic metrology data, as discussed at block 440 in FIG. 4B, or a spectral transformation between the measured metrology data and the first set of synthetic metrology data as illustrated at block 442 in FIG. 4C.

In some implementations, at least one processor may produce the composite metrology data for the modified reference device by determining a difference between the first set of synthetic metrology data and the second set of synthetic metrology data, e.g., as discussed in reference to FIG. 4A and illustrated at block 444 in FIGS. 4D and 4E. The at least one processor may further modify the measured metrology data with the difference between the first set of synthetic metrology data and the second set of synthetic metrology data as discussed in reference to FIG. 4A and illustrated at block 444 and 450 in FIGS. 4D and 4E.

In some implementations, at least one processor may further produce a plurality of sets of composite metrology data for a corresponding plurality of modified reference devices and store the plurality of sets of the composite metrology data as the training data set.

The measured metrology data, for example, may be measured spectra and the first set of synthetic metrology data and the second set of synthetic metrology data may be synthetic spectra.

In some implementations, at least one processor may further generate a first set of key parameter values for the first model of the reference device, e.g., as discussed at block 522 of FIG. 5. The at least one processor may further generate a second set of key parameter values for the second model (if used), e.g., as discussed at block 532 of FIG. 5. The at least one processor may produce composite reference parameters for the modified reference device by merging the reference parameters, the first set of key parameter values and the second set of key parameters values (if used), e.g., as discussed at blocks 512, 540, and 550. The at least one processor may store the composite reference parameters with the composite metrology data as the training data set, e.g., in memory 164 shown in FIG. 1. For example, the composite reference parameters for the modified reference device may be produced by determining a key parameter bias between the first set of key parameter values and the second set of key parameters values, e.g., as discussed at block 540 of FIG. 5, and modifying the reference parameters with the key parameter bias, e.g., as discussed at block 550 of FIG. 5.

The above description is intended to be illustrative, and not restrictive. For example, the above-described examples (or one or more aspects thereof) may be used in combination with each other. Other implementations can be used, such as by one of ordinary skill in the art upon reviewing the above description. Also, various features may be grouped together and less than all features of a particular disclosed implementation may be used. Thus, the following aspects are hereby incorporated into the above description as examples or implementations, with each aspect standing on its own as a separate implementation, and it is contemplated that such implementations can be combined with each other in various combinations or permutations. Therefore, the spirit and scope of the appended claims should not be limited to the foregoing description.

What is claimed is:

1. A method for characterizing a device on a sample comprising:
obtaining measured metrology data from the device; and
determining, based on the measured metrology data, at least one parameter of the device with a machine learning model that uses composite metrology data, wherein each composite metrology datum comprises a merger of a metrology datum measured for a reference device and a first synthetic metrology datum for a first model of the reference device.

2. The method of claim 1, wherein the first model is produced by fitting metrology data measured from the reference device to synthetic metrology data for the first model.

3. The method of claim 1, wherein each composite metrology datum comprises the merger of the metrology datum and the first synthetic metrology datum and further a second synthetic metrology datum for a second model of a modified reference device that is changed with respect to the first model.

4. The method of claim 3, wherein the second model of the modified reference device has at least one parameter that is varied with respect to the first model.

5. The method of claim 3, wherein the machine learning model further uses composite reference parameters for the modified reference device based on a merger of reference parameters of the reference device, a first set of key parameter values generated for the first model, and a second set of key parameters values generated for the second model.

6. The method of claim 3, wherein the second model of the modified reference device is produced by changing at least one parameter of the first model.

7. The method of claim 3, wherein second synthetic metrology data for the second model of the modified reference device is generated based on a variation between metrology data measured from the reference device and first synthetic metrology data for the first model.

8. The method of claim 3, wherein the composite metrology data is generated by modifying metrology data measured from the reference device with a determined difference between first synthetic metrology data for the first model and second synthetic metrology data for the second model of the modified reference device.

9. The method of claim 3, wherein the composite metrology data comprises a plurality of sets of composite metrology data for a corresponding plurality of modified reference devices.

10. The method of claim 1, wherein the measured metrology data comprises measured spectra and the composite metrology data comprises composite spectra.

11. A metrology system configured for supporting characterizing a device on a sample comprising:
a source configured to generate radiation to be incident on the device on the sample;
at least one detector configured to detect radiation from the device produced in response to the radiation that is incident on the device; and
at least one processor coupled to the at least one detector, wherein the at least one processor is configured to:
obtain measured metrology data from the device; and
determine, based on the measured metrology data, at least one parameter of the device with a machine learning model that uses composite metrology data, wherein each composite metrology datum comprises a merger of a metrology datum measured for a reference device and a first synthetic metrology datum for a first model of the reference device.

12. The metrology system of claim 11, wherein the first model is produced by fitting metrology data measured from the reference device to synthetic metrology data for the first model.

13. The metrology system of claim 11, wherein each composite metrology datum comprises the merger of the metrology datum and the first synthetic metrology datum and further a second synthetic metrology datum for a second model of a modified reference device that is changed with respect to the first model.

14. The metrology system of claim 13, wherein the second model of the modified reference device has at least one parameter that is varied with respect to the first model.

15. The metrology system of claim 13, wherein the machine learning model further uses composite reference parameters for the modified reference device based on a merger of reference parameters of the reference device, a first set of key parameter values generated for the first model, and a second set of key parameters values generated for the second model.

16. The metrology system of claim 13, wherein the second model of the modified reference device is produced by changing at least one parameter of the first model.

17. The metrology system of claim 13, wherein second synthetic metrology data for the second model of the modified reference device is generated based on a variation between metrology data measured from the reference device and first synthetic metrology data for the first model.

18. The metrology system of claim 13, wherein the composite metrology data is generated by modifying metrology data measured from the reference device with a determined difference between first synthetic metrology data for the first model and second synthetic metrology data for the second model of the modified reference device.

19. The metrology system of claim 13, wherein the composite metrology data comprises a plurality of sets of composite metrology data for a corresponding plurality of modified reference devices.

20. The metrology system of claim 11, wherein the measured metrology data comprises measured spectra and the composite metrology data comprises composite spectra.

21. A metrology system configured for supporting characterizing a device on a sample comprising:
means for obtaining measured metrology data from the device; and
means for determining, based on the measured metrology data, at least one parameter of the device with a machine learning model that uses composite metrology data, wherein each composite metrology datum comprises a merger of a metrology datum measured for a reference device and a first synthetic metrology datum for a first model of the reference device.

22. The metrology system of claim 21, wherein each composite metrology datum comprises the merger of the metrology datum and the first synthetic metrology datum and further a second synthetic metrology datum for a second model of a modified reference device that is changed with respect to the first model.
